(19) United States
(12) Patent Application Publication
(10) Pub. No.: US 2025/0385100 A1
(43) Pub. Date: Dec. 18, 2025

(54) METHOD OF MANUFACTURING SEMICONDUCTOR DEVICE

(71) Applicant: Samsung Electronics Co., Ltd., Suwon-si (KR)

(72) Inventor: Taehyuk KIM, Suwon-si (KR)

(73) Assignee: Samsung Electronics Co., Ltd., Suwon-si (KR)

(21) Appl. No.: 19/021,720

(22) Filed: Jan. 15, 2025

(30) Foreign Application Priority Data
Jun. 18, 2024 (KR) 10-2024-0079099

(51) Int. Cl. H01L 21/311; H01L 21/027; H01L 23/544

(52) U.S. Cl. CPC H01L 21/31144; H01L 21/0271; H01L 23/544; H01L 2223/5446

(57) ABSTRACT

A method of manufacturing a semiconductor device may forming a first photoresist pattern on a stacked structure, the first photoresist pattern including a second portion surrounding first portions having a line-and-space shape, transferring a pattern of the first photoresist pattern to a first mask layer, forming a spacer insulating layer covering sidewalls of remaining portions of the first mask layer, forming a second mask layer filling spaces between portions of the spacer insulating layer, removing the spacer insulating layer, forming first insulating patterns having a line and space shape and a second insulating pattern surrounding the first insulating patterns using the first mask layer and the second mask layer as masks, forming a trench by removing the first insulating patterns using a second photoresist pattern as a mask, and forming a trench key by transferring a pattern of the trench to a lower region of the stacked structure.

### CROSS-REFERENCE TO RELATED APPLICATION

This application is based on and claims priority under 35 U.S.C. § 119 to Korean Patent Application No. 10-2024-0079099, filed on Jun. 18, 2024, in the Korean Intellectual Property Office, the disclosure of which is incorporated by reference herein in its entirety.

### BACKGROUND

Inventive concepts relate to a method of manufacturing a semiconductor device, and more particularly, to a method of manufacturing a semiconductor device including a trench key in a scribe lane area.

In accordance with the development of the electronics industry and consumer demands, down-scaling of semiconductor devices is rapidly progressing. However, it may be increasingly difficult to manufacture semiconductor devices due to decreasing process margins in the manufacturing process of semiconductor device. Accordingly, it may be advantageous to develop a technology capable of manufacturing semiconductor devices having finer patterns.

### SUMMARY

Inventive concepts provide a method of manufacturing a semiconductor device having improved reliability.

According to an embodiment of inventive concepts, a method of manufacturing a semiconductor device may include forming a stacked structure on a substrate; forming a first photoresist pattern on the stacked structure, the first photoresist pattern including first portions having a line-and-space shape and a second portion horizontally surrounding the first portions; transferring a pattern of the first photoresist pattern to a first mask layer of the stacked structure by removing portions of the first mask layer using the first photoresist pattern as a mask to form remaining portions of the first mask layer; forming a spacer insulating layer covering sidewalls of the remaining portions of the first mask layer; forming a second mask layer filling spaces between portions of the spacer insulating layer; forming first insulating patterns and a second insulating pattern, the first insulating patterns having a line and space shape, the second insulating pattern horizontally surrounding the first insulating patterns, the forming the first insulating patterns and the second insulating pattern including removing the spacer insulating layer and using the remaining portions of the first mask layer and the second mask layer as masks; forming a second photoresist pattern on the substrate, the second photoresist pattern exposing the first insulating patterns; forming a trench defined by the second insulating pattern by removing the first insulating patterns; and forming a trench key by transferring a pattern of the trench to a lower region of the stacked structure using the second insulating pattern as a mask.

According to embodiment of inventive concepts, a method of manufacturing a semiconductor device may include forming a stacked structure on a substrate including a chip area and a scribe lane area; forming first photoresist patterns having a line and space shape on the stacked structure; transferring a pattern of the first photoresist patterns to a first mask layer of the stacked structure; forming a spacer insulating layer covering sidewalls of the first mask layer after the transferring the pattern of the first photoresist patterns to the first mask layer; forming a second mask layer filling spaces between portions of the spacer insulating layer; forming first insulating patterns and a second insulating pattern using the first mask layer and the second mask layer as masks, the first insulating patterns having a line-and-space shape and the second insulating pattern horizontally surrounding the first insulating patterns; forming a trench defined by the second insulating pattern by removing the first insulating patterns using a second photoresist pattern covering the second insulating pattern as a mask; and forming a trench key in the scribe lane area by transferring a pattern of the trench to a lower region of the stacked structure using the second insulating pattern as a mask.

According to embodiment of inventive concepts, a method of manufacturing a semiconductor device may include forming a stacked structure including a first mask layer, a first insulating layer, and a second insulating layer on a substrate including a chip area and a scribe lane area; forming a first photoresist pattern on the stacked structure, the first photoresist pattern including first portions having a line-and-space shape and a second portion horizontally surrounding the first portions; transferring a pattern of the first photoresist pattern to the first mask layer by removing portions of the first mask layer using the first photoresist pattern as a mask to form remaining portions of the first mask layer; forming a spacer insulating layer covering sidewalls of the remaining portions of the first mask layer; forming a second mask layer filling spaces between portions of the spacer insulating layer; forming first insulating patterns and a second insulating pattern, the first insulating patterns having a line and space shape, the second insulating pattern horizontally surrounding the first insulating patterns, the forming the first insulating patterns and the second insulating pattern including removing portions of the first insulating layer using the first mask layer and the second mask layer as masks; forming a second photoresist pattern on the second insulating pattern, the second photoresist pattern exposing the first insulating patterns; forming a trench defined by the second insulating pattern by removing the first insulating patterns using the second photoresist pattern as a mask; removing the second photoresist pattern from surfaces of the second insulating pattern; and forming a trench key by transferring a pattern of the trench to a lower region of the stacked structure using the second insulating pattern as a mask, the trench key passing through the second insulating layer and extending into the substrate.

### BRIEF DESCRIPTION OF THE DRAWINGS

Embodiments will be more clearly understood from the following detailed description taken in conjunction with the accompanying drawings in which:

FIG. 1 is a schematic layout of a semiconductor device according to some embodiments;

FIG. 2 is a schematic layout of a key pattern of a semiconductor device according to some embodiments;

FIG. 3 is a flowchart of a method of manufacturing a key pattern of a semiconductor device according to some embodiments; and

FIGS. 4A to 10B are diagrams to explain a method of manufacturing a key pattern of a semiconductor device according to some embodiments.

### DETAILED DESCRIPTION OF THE EMBODIMENTS

Hereinafter, embodiments are described in detail with reference to the accompanying drawings. The same reference numerals are used for the same components in the drawings, and duplicate descriptions thereof are omitted.

It will be understood that, although the terms “first”, “second”, etc. may be used herein to describe various elements, components, regions, layers and/or sections. These elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

The notion that elements are “substantially the same” may indicate that the element may be completely the same and may also indicate that the elements may be determined to be the same in consideration of errors or deviations occurring during a process.

While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., ±10%).

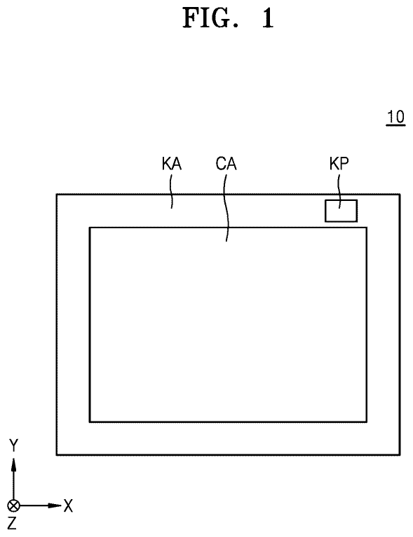

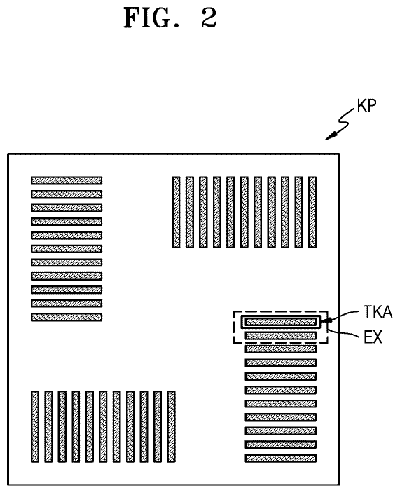

FIG. 1 is a schematic layout of a semiconductor device 10 according to some embodiments. FIG. 2 is a schematic layout of a key pattern KP of the semiconductor device 10 according to some embodiments.

Referring to FIGS. 1 and 2, the semiconductor device 10 may include a chip area CA and a scribe lane area KA. The chip area CA may include one of a plurality of semiconductor chips formed on a semiconductor wafer. The chip area CA may include, for example, a DRAM chip in which DRAM components are formed. The chip area CA may include a cell area in which memory cells are formed and a peripheral circuit area in which peripheral circuits that control the memory cells are formed. In some embodiments, the cell area may include a horizontal channel transistor. In some embodiments, the cell area may include a vertical channel transistor (VCT).

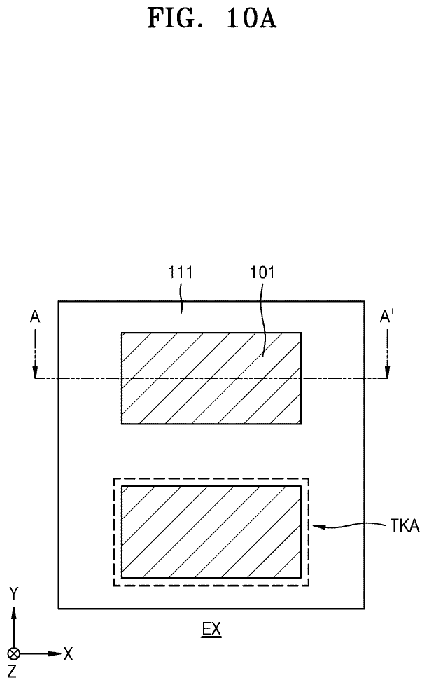

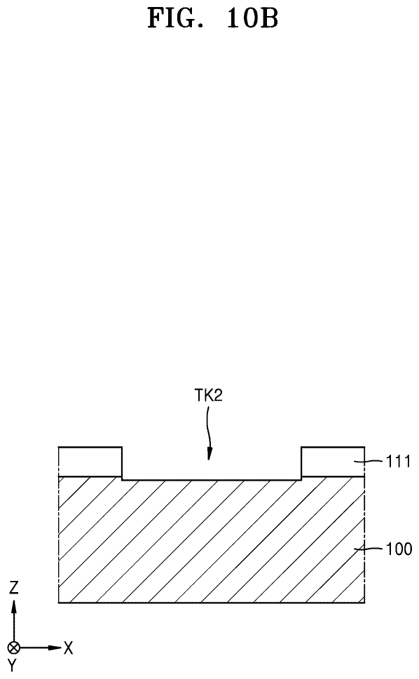

The scribe lane area KA may include a key pattern KP around the chip area CA. The key pattern KP may include, for example, a gate alignment key pattern or a contact alignment key pattern. Unlike as shown in FIG. 1, there may be a plurality of key patterns KP. The key pattern KP may include a plurality of trench areas TKA. Each of the plurality of trench areas TKA may include a trench key TK2 (see FIG. 10B). The plurality of trench areas TKA may be arranged in a pinwheel shape to be spaced apart from each other in a first horizontal direction (X direction) and a second horizontal direction (Y direction) within the key pattern KP. However, inventive concepts are not limited thereto and the plurality of trench areas TKA in the key pattern KP may be arranged differently from those illustrated in FIG. 2.

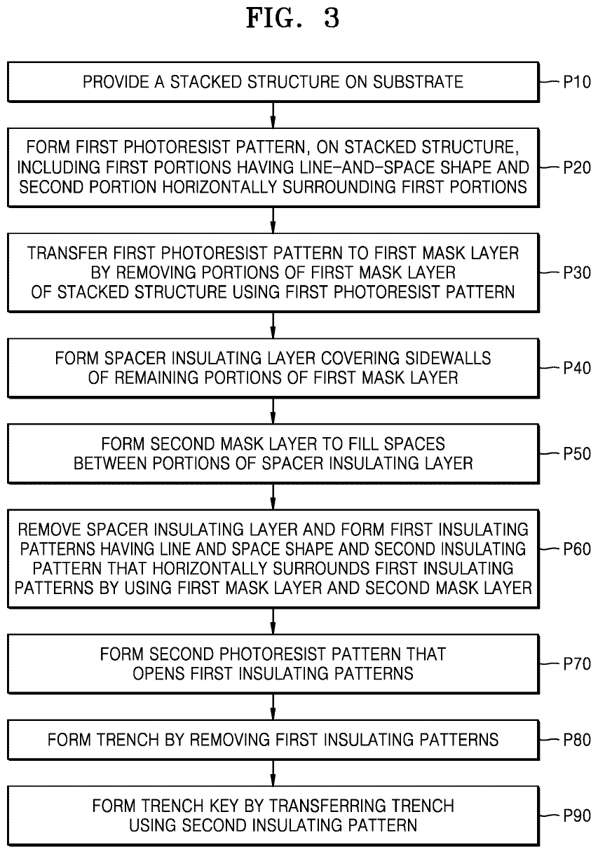

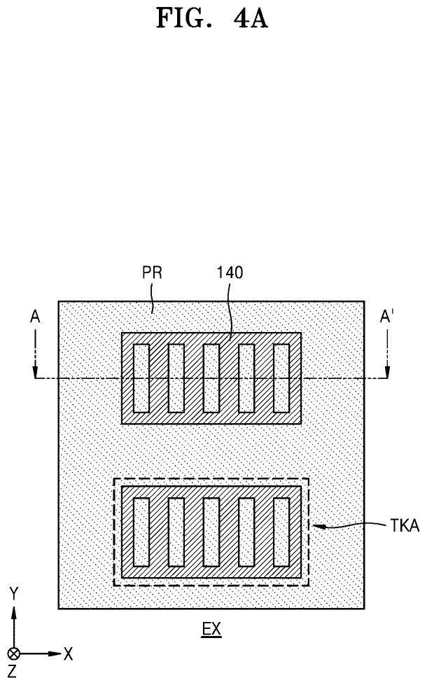

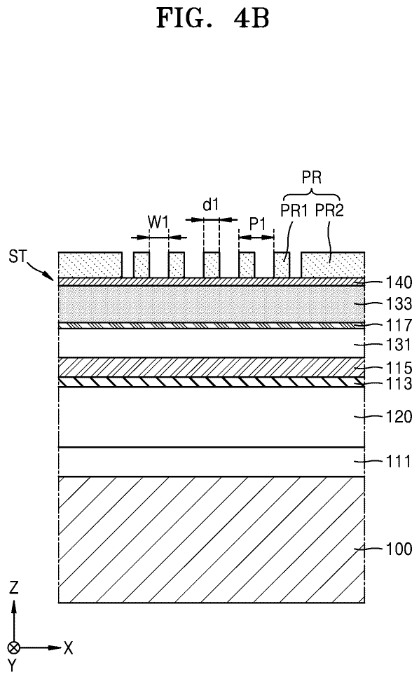

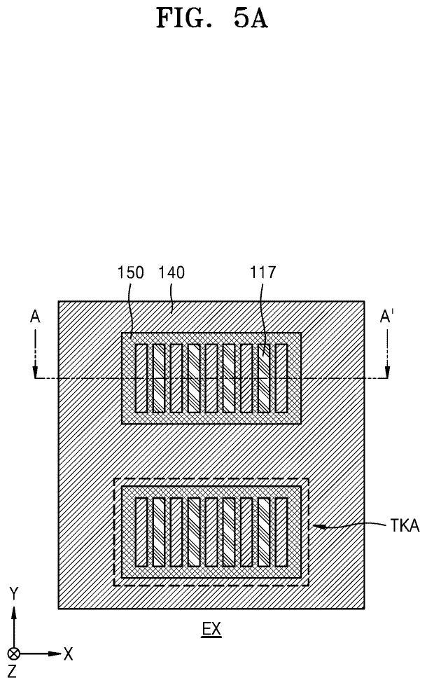

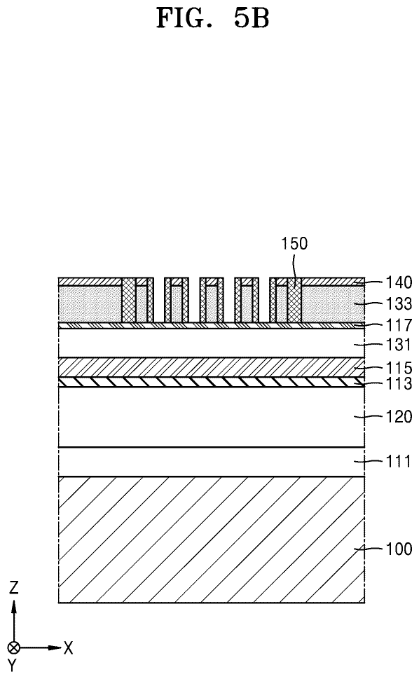

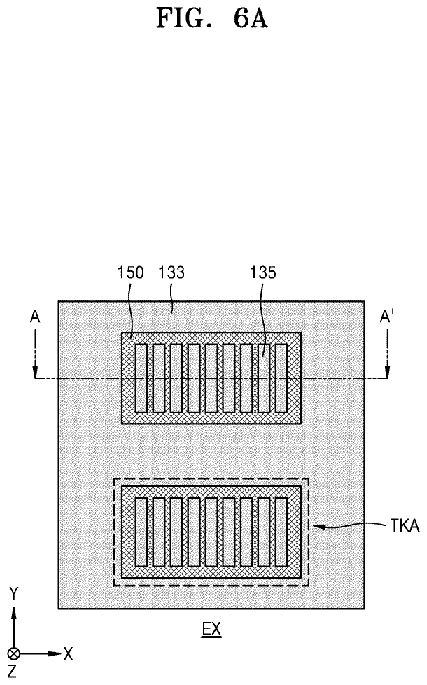

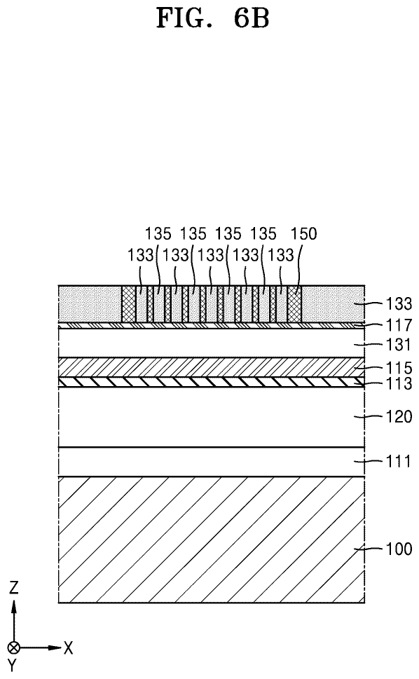

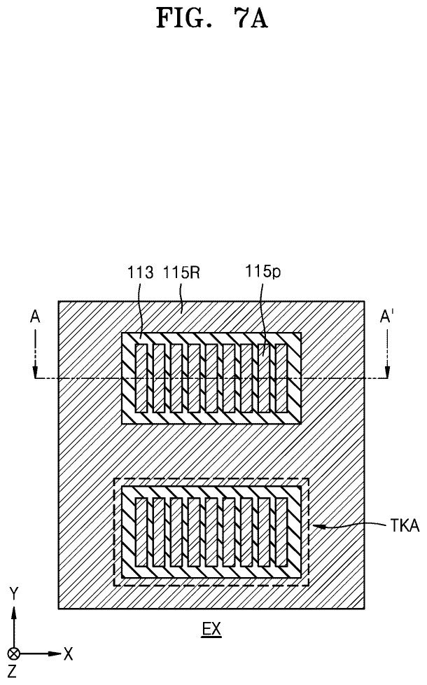

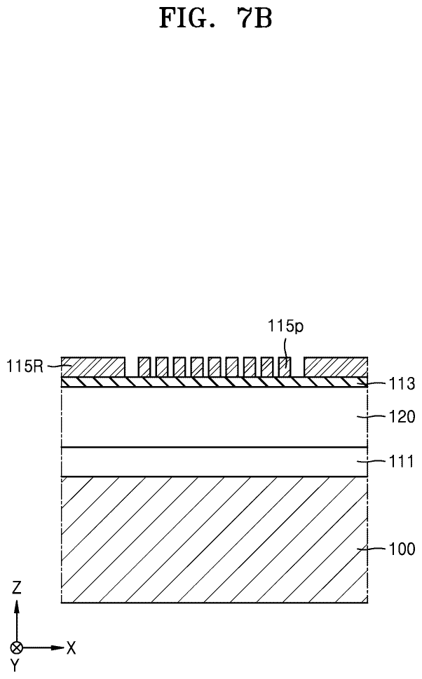

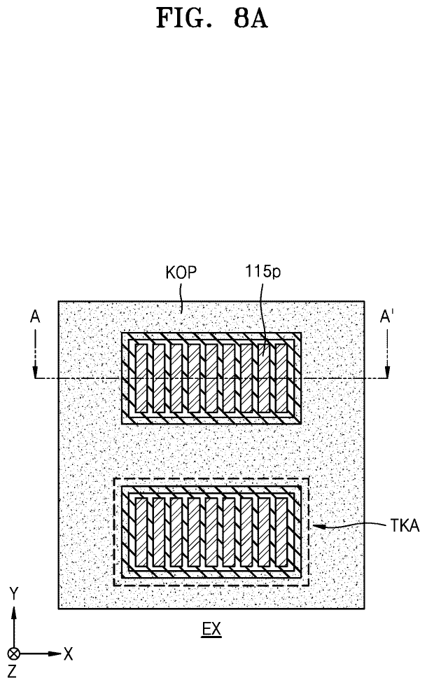

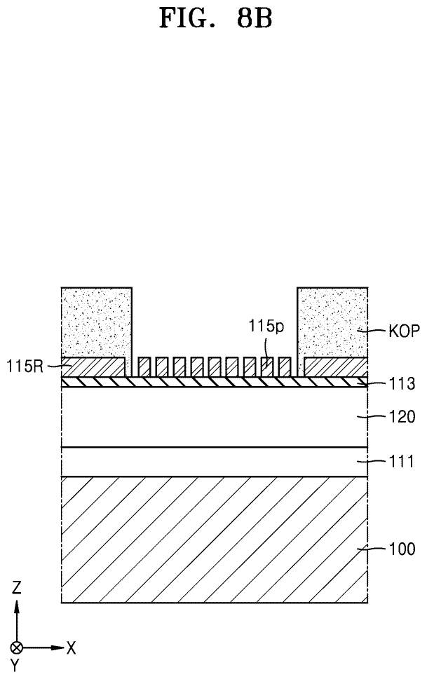

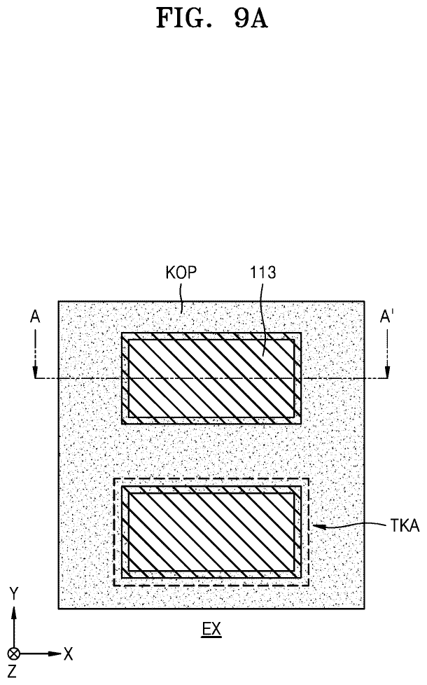

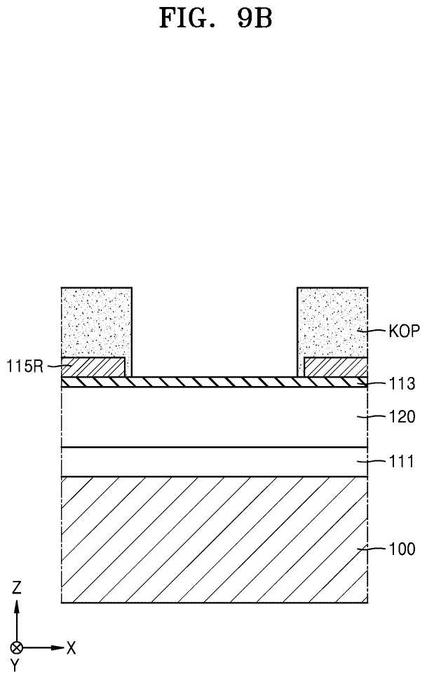

FIG. 3 is a flowchart of a method of manufacturing a key pattern of a semiconductor device according to some embodiments. FIGS. 4A to 10B are diagrams to explain a method of manufacturing a key pattern of a semiconductor device according to some embodiments. Specifically, FIG. 4A, FIG. 5A, FIG. 6A, FIG. 7A, FIG. 8A, FIG. 9A, and FIG. 10A are enlarged plan views of portion “EX” in FIG. 2 and FIG. 4B, FIG. 5B, FIG. 6B, FIG. 7B, FIG. 8B, FIG. 9B, and FIG. 10B are cross-sectional views taken along line A-A′ in FIG. 4A, FIG. 5A, FIG. 6A, FIG. 7A, FIG. 8A, FIG. 9A, and FIG. 10A, respectively.

Referring to FIGS. 3, 4A, and 4B, a stacked structure ST may be provided on a substrate 100 (P10). The substrate 100 may include a semiconductor, such as Si or Ge, or a compound semiconductor, such as SiGe, SiC, GaAs, InAs, InGaAs, or InP. As used herein, the terms “SiGe,” “SiC,” “GaAs,” “InAs,” “InGaAs” and “InP” refer to materials of elements included in each term and are not chemical formulas that represent stoichiometric relationships. The substrate 100 may include the chip area CA (see FIG. 1) and the scribe lane area KA as illustrated in FIGS. 1 and 2. Although only the scribe lane area KA is shown in the following drawings for convenience of description, inventive concepts are not limited thereto. An upper region of the substrate 100 may include a doped region doped with impurities. The impurities may include, for example, n-type impurities or p-type impurities. The n-type impurities may include, for example, phosphorus, arsenic, antimony, and the like. The p-type impurities may include, for example, boron, aluminum, gallium, indium, and the like.

The stacked structure ST may include a first insulating layer 111, a first mask layer 120, a second insulating layer 113, a third insulating layer 115, a second mask layer 131, a fourth insulating layer 117, a third mask layer 133, and a fifth insulating layer 140, which are sequentially stacked in a vertical direction (Z direction) on an upper surface of the substrate 100. The first insulating layer 111, the second insulating layer 113, the third insulating layer 115, the fourth insulating layer 117, and the fifth insulating layer 140 may each include an oxide, a nitride, or a combination thereof. For example, the first insulating layer 111, the second insulating layer 113, the third insulating layer 115, the fourth insulating layer 117, and the fifth insulating layer 140 may each include a silicon nitride, a silicon oxide, a silicon oxynitride, or a combination thereof. The first mask layer 120 may include an amorphous carbon layer made of amorphous carbon and the second mask layer 131 and the third mask layer 133 may each include carbon. The second mask layer 131 and the third mask layer 133 may include, for example, carbon-based spin-on-hardmask layers but are not limited thereto.

Next, a first photoresist pattern PR may be formed on the stacked structure ST (P20). The first photoresist pattern PR may expose portions of an upper surface of the fifth insulating layer 140. In a plan view, the first photoresist pattern PR may include first portions PR1 surrounded by the exposed fifth insulating layer 140 and a second portion PR2 surrounding the exposed fifth insulating layer 140. The first portions PR1 may have a line-and-space shape in which a plurality of bars are arranged in the first horizontal direction (X direction) and are spaced apart from each other in the first horizontal direction (X direction).

In some embodiments, a width d1 of each of the first portions PR1 of the first photoresist pattern PR may be substantially equal to a width of each of cell nodes of the chip area CA of the semiconductor device 10 illustrated in FIGS. 1 and 2. The width of the cell node of the chip area CA of the semiconductor device 10 may refer to a width of the transistor included in the chip area CA of the semiconductor device 10. The width d1 may refer to a length of the first portion PR1 of the first photoresist pattern PR in the first horizontal direction (X direction).

In some embodiments, a distance WI between the first portions PR1 of the first photoresist pattern PR may be substantially equal to a distance between the cell nodes of the chip area CA of the semiconductor device 10 illustrated in FIGS. 1 and 2. The distance between the cell nodes of the chip area CA of the semiconductor device 10 may refer to a distance between the transistors included in the chip area CA of the semiconductor device 10. In addition, the distance WI may refer to a length between any one of the first portions PR1 of the first photoresist pattern PR and another adjacent one of the first portions PR1 of the first photoresist pattern PR in the first horizontal direction (X direction).

In some embodiments, a pitch P1 between the first portions PR1 of the first photoresist pattern PR may be substantially equal to a pitch between the cell nodes of the chip area CA of the semiconductor device 10 illustrated in FIGS. 1 and 2. The pitch between the cell nodes of the chip area CA of the semiconductor device 10 may refer to a pitch between the transistors included in the chip area CA of the semiconductor device 10. The pitch P1 may refer to a length between a surface of any one of the first portions PR1 of the first photoresist pattern PR and a surface of another adjacent one of the first portions PR1 corresponding to the surface of any one of the first portions PR1 in the first horizontal direction (X direction).

Referring to FIGS. 3, 5A, and 5B, in the result of FIGS. 4A and 4B, portions of the fifth insulating layer 140 exposed by the first photoresist pattern PR (see FIG. 4A) by using the first photoresist pattern PR (see FIG. 4A) as an etch mask and portions of the third mask layer 133 which overlap with the portions of the fifth insulating layer 140 exposed by the first photoresist pattern PR (see FIG. 4A) in the vertical direction (Z direction) may be removed (P30). Through the etching process, the first photoresist pattern PR (see FIG. 4A) may be transferred to the fifth insulating layer 140 and the third mask layer 133. The pattern transferred to the third mask layer 133 may include the line-and-space shape, such as the first portions PR1 of the first photoresist pattern PR (see FIG. 4A). The removed portions of the fifth insulating layer 140 and the third mask layer 133 may expose portions of an upper surface of the fourth insulating layer 117.

Next, the first photoresist pattern PR (see FIG. 4A) may be removed from an upper surface of the fifth insulating layer 140 to form a spacer insulating layer 150 (P40). The spacer insulating layer 150 may be formed by forming an insulating material which fills the space formed by removing each portion of the fifth insulating layer 140 and the third mask layer 133 in the above-described process and covers upper surfaces of the remaining portions of the fifth insulating layer 140 and by removing portions of the insulating material. The spacer insulating layer 150 may cover sidewalls of each remaining portion of the fifth insulating layer 140 and the third mask layer 133. In a plan view, the fifth insulating layer 140 and the fourth insulating layer 117 of which portions are exposed by removing the portions of the fifth insulating layer 140 and the third mask layer 133 may be spaced apart from each other in the first horizontal direction (X direction) and may be alternately arranged in the first horizontal direction (X direction). The spacer insulating layer 150 may include, for example, an oxide such as a silicon oxide.

Referring to FIGS. 3, 6A, and 6B, in the result of FIGS. 5A and 5B, a fourth mask layer 135 may be formed to cover upper surfaces of the exposed portions of the fourth insulating layer 117, wherein the exposed portion of the fourth insulating layer 117 are exposed by removing the portions of the fifth insulating layer 140 (see FIG. 5A) and the third mask layer 133. In some embodiments, the fourth mask layer 135 may be formed so that an upper surface of the fourth mask layer 135 is positioned at the same vertical level as the upper surface of the remaining fifth insulating layer 140 (see FIG. 5A). In some embodiments, the fourth mask layer 135 may be formed so that an upper surface of the fourth mask layer 133 is located at a higher vertical level than the upper surface of the remaining fifth insulating layer 140 (see FIG. 5A). In this case, the fourth mask layer 135 may cover the upper surface of the remaining fifth insulating layer 140 (see FIG. 5A). The fourth mask layer 135 may include, for example, a spin-on-hardmask layer made of carbon but is not limited thereto.

Next, the fifth insulating layer 140 (see FIG. 5A) may be removed from the upper surface of the third mask layer 133. The fifth insulating layer 140 (see FIG. 5A) may be removed, for example, by an etch back process. In the process of removing the fifth insulating layer 140 (see FIG. 5A), portions of the fourth mask layer 135 and portions of the spacer insulating layer 150 that horizontally overlap with the fifth insulating layer 140 (see FIG. 4A) may also be removed together with the fifth insulating layer 140 (see FIG. 5A). Accordingly, each upper surface of the fourth mask layer 135, the third mask layer 133, and the spacer insulating layer 150 may be located at the same vertical level.

The fourth mask layer 135 and the third mask layer 133 may be spaced apart from each other in the first horizontal direction (X direction) with the spacer insulating layer 150 therebetween. In a plan view, the fourth mask layer 135 and the portions of the third mask layer 133 surrounded by the spacer insulating layer 150 may together form a pattern in the line-and-space shape. The pattern in the line-and-space shape formed by the fourth mask layer 135 and the portions of the third mask layer 133 surrounded by the spacer insulating layer 150 may have a pitch less than the pattern in the line-and-space shape of the first portion PR1 of the first photoresist pattern PR (see FIG. 4A).

Referring to FIGS. 3, 7A, and 7B, in the result of FIGS. 6A and 6B, the spacer insulating layer 150 (see FIG. 6A) may be removed. Next, the portions of the fourth insulating layer 117 (see FIG. 6A) exposed by the third mask layer 133 (see FIG. 6A) and the fourth mask layer 135 (see FIG. 6A) may be removed by using the third mask layer 133 (see FIG. 6A) and the fourth mask layer 135 (FIG. 6A) as an etching mask.

Next, the third mask layer 133 (see FIG. 6A) and the fourth mask layer 135 (see FIG. 6A) may be removed from the upper surface of the fourth insulating layer 117 (see FIG. 6A). Each of the third mask layer 133 (see FIG. 6A) and the fourth mask layer 135 (see FIG. 6A) may be removed, for example, by an etch back process.

Next, the remaining fourth insulating layer 117 (see FIG. 6A) may be used as an etching mask to remove portions of the second mask layer 131 (see FIG. 6A) and portions of the third insulating layer 115 (see FIG. 6A). Next, the second mask layer 131 (refer to FIG. 6A) may be removed from an upper surface of the third insulating layer 115 (refer to FIG. 6A).

The pattern in the line-and-space shape formed by the fourth mask layer 135 (see FIG. 6A) and the portions of the third mask layer 133 (see FIG. 6A) surrounded by the spacer insulating layer 150 (see FIG. 6A) may be transferred to the third insulating layer 115 (see FIG. 6A) through the fourth insulating layer 117 (see FIG. 6A) and the second mask layer 131 (see FIG. 6A) by performing the process described above with reference to FIGS. 7A and 7B. Through the above-described process, the portions of the third insulating layer 115 (see FIG. 6A) overlapping with the spacer insulating layer 150 (FIG. 6A) in the vertical direction (Z direction) may be removed and the pattern in the line-and-space shape formed by the fourth mask layer 135 (see FIG. 6A) and the portions of the third mask layer 133 (see FIG. 6A) surrounded by the spacer insulating layer 150 (see FIG. 6A) may be transferred to form a plurality of first insulating patterns 115p having the line-and-space shape and a second insulating pattern 115R surrounding the first insulating patterns 115p horizontally. The plurality of first insulating patterns 115p and the second insulating pattern 115R may expose portions of an upper surface of the second insulating layer 113.

Referring to FIGS. 3, 8A, and 8B, a second photoresist pattern KOP covering an upper surface of the second insulating pattern 115R may be formed in the result of FIGS. 7A and 7B. That is, the second photoresist pattern KOP may be formed on the second insulating pattern 115R when both the second mask layer 131 (see FIG. 6A) and the third mask layer 133 (see FIG. 6A) are removed. In some embodiments, the second photoresist pattern KOP may cover inner walls of the second insulating pattern 115R. In other embodiments, the second photoresist pattern KOP may not cover the inner walls of the second insulating pattern 115R, unlike illustrated in FIG. 8B. In this case, sidewalls of the second photoresist pattern KOP may be located on the same plane as the inner walls of the second insulating pattern 115R in the vertical direction (Z direction). By the second photoresist pattern KOP, the second insulating pattern 115R may be closed and the first insulating patterns 115p may be opened.

Referring to FIGS. 3, 9A, and 9B, in the result of FIGS. 8A and 8B, the first insulating patterns 115p (see FIG. 8A) may be removed by using the second photoresist pattern KOP as an etching mask. By removing the first insulating patterns 115p, a trench exposing a portion of the upper surface of the second insulating layer 113 may be formed inside the second insulating pattern 115R.

The first insulating patterns 115p (see FIG. 8A) may be removed, for example, by a strip process. The strip process may include, for example, a wet strip process, but is not limited thereto, and the strip process may include a dry strip process. Even when the wet strip process is performed to remove the first insulating patterns 115p, the second insulating pattern 115R may be protected by the second photoresist pattern KOP covering the inner walls of the second insulating pattern 115R. Accordingly, the trench key TK2 formed by using the second insulating pattern 115R as an etching mask in a process to be described later may be formed as designed without being damaged.

Referring to FIGS. 3, 10A, and 10B, in the result of FIGS. 9A and 9B, the second photoresist pattern KOP (see FIG. 9A) may be removed from surfaces of the second insulating pattern 115R (see FIG. 8A) and an upper surface of the second insulation layer 113 (see FIG. 6A). The second photoresist pattern KOP (see FIG. 9A) may be removed, for example, by an ashing process or a strip process. By removing the second photoresist pattern KOP (see FIG. 9A), the second insulating pattern 115R (see FIG. 8A) may be exposed.

Next, by performing an etching process using the second insulating pattern 115R (see FIG. 9A) as an etching mask, the trench key TK2 which passes through a portion of the first insulating layer 111 and extends into the substrate 100 in the vertical direction (Z direction) may be formed. By the etching process, the trench formed inside the second insulating pattern 115R may be transferred to the trench key TK2 which passes through the portion of the first insulating layer 111 through the second insulating layer 113 and the first mask layer 120 and extends into the substrate 100 in the vertical direction (Z direction).

The trench key TK2 may be formed in the trench area TKA surrounded by the first insulating layer 111 in a plan view. The trench key TK2 may be used as a gate alignment key or a contact alignment key of the semiconductor device 10 in a process of manufacturing the semiconductor device 10 (see FIG. 1).

A method of manufacturing a semiconductor device according to some embodiments includes forming the first insulating patterns 115p in a line-and-space shape by using the second mask layer 131, the third mask layer 133, and the fourth mask layer 135, and the second insulating pattern 115R surrounding the first insulating patterns 115p, forming the second photoresist pattern KOP covering the second insulating pattern 115R after removing the second mask layer 131, the third mask layer 133, and the fourth mask layer 135, removing the first insulating patterns 115p by using the second photoresist pattern KOP to form the trench, and transferring the trench to the first insulating layer 111 and the substrate 100 to form the trench key TK2.

When forming the second photoresist pattern KOP on the second mask layer 131 and the third mask layer 133, forming the trench by using the second photoresist pattern KOP as an etching mask, and transferring the trench to form the trench key TK2, the third mask layer 133 may be damaged in the process of forming the trench and the third mask layer 135 may be lifted. As a result, the trench key TK2 may not be properly formed.

According to some embodiments, the first insulating patterns 115p in the line-and-space shape may be formed before forming the second photoresist pattern KOP, the second photoresist pattern KOP may be formed by removing the second mask layer 131, the third mask layer 133, and the fourth mask layer 135, and the trench may be formed by removing the first insulating patterns 115p using the second photoresist pattern KOP as an etch mask. Accordingly, the semiconductor device 10 with improved reliability may be manufactured by forming the trench key TK2 without the lifting of the third mask layer 135 and by using the trench key TK2 formed as designed as an overlay key in the process of manufacturing the semiconductor device 10.

While inventive concepts have been particularly shown and described with reference to embodiments thereof, it will be understood that various changes in form and details may be made therein without departing from the spirit and scope of the following claims.

What is claimed is:

1. A method of manufacturing a semiconductor device, the method comprising:
forming a stacked structure on a substrate;
forming a first photoresist pattern on the stacked structure, the first photoresist pattern including first portions having a line-and-space shape and a second portion horizontally surrounding the first portions;
transferring a pattern of the first photoresist pattern to a first mask layer of the stacked structure by removing portions of the first mask layer using the first photoresist pattern as a mask to form remaining portions of the first mask layer;
forming a spacer insulating layer covering sidewalls of the remaining portions of the first mask layer;
forming a second mask layer filling spaces between portions of the spacer insulating layer;
forming first insulating patterns and a second insulating pattern, the first insulating patterns having a line and space shape, the second insulating pattern horizontally surrounding the first insulating patterns, the forming the first insulating patterns and the second insulating pattern including removing the spacer insulating layer and using the remaining portions of the first mask layer and the second mask layer as masks;
forming a second photoresist pattern on the substrate, the second photoresist pattern exposing the first insulating patterns;
forming a trench defined by the second insulating pattern by removing the first insulating patterns; and
forming a trench key by transferring a pattern of the trench to a lower region of the stacked structure using the second insulating pattern as a mask.

2. The method of claim 1, wherein
the semiconductor device comprises a chip area and a scribe lane area and the trench key is in the scribe lane area.

3. The method of claim 2, wherein a width of one of the first portions of the first photoresist pattern is equal to a width of a cell node included in the chip area.

4. The method of claim 2, wherein a distance between the first portions of the first photoresist pattern is equal to a distance between cell nodes included in the chip area.

5. The method of claim 2, wherein a pitch between the first portions of the first photoresist pattern is equal to a pitch between cell nodes included in the chip area.

6. The method of claim 1, wherein the second photoresist pattern is formed on the second insulating pattern and covers inner walls of the second insulating pattern.

7. The method of claim 1, wherein
in the forming the trench, the removing the first insulating patterns is performed by a wet strip process.

8. The method of claim 1, wherein
the second photoresist pattern is formed on the second insulating pattern, and
inner walls of the second photoresist pattern are coplanar with inner walls of the second insulating pattern.

9. The method of claim 1, wherein, after the removing portions of the first mask layer is performed and the forming the second mask layer is performed, the remaining portions of the first mask layer and the second mask layer form a pattern in a line-and-space shape.

10. The method of claim 9, wherein
a pitch of the pattern in the line-and-space shape is less than a pitch of the first portions of the first photoresist pattern.

11. The method of claim 1, wherein
the first insulating patterns by transferring a pattern in the line-and-space shape that is formed by the portions of the first mask layer and the second mask layer.

12. A method of manufacturing a semiconductor device, the method comprising:
forming a stacked structure on a substrate including a chip area and a scribe lane area;
forming first photoresist patterns having a line and space shape on the stacked structure;
transferring a pattern of the first photoresist patterns to a first mask layer of the stacked structure;
forming a spacer insulating layer covering sidewalls of the first mask layer after the transferring the pattern of the first photoresist patterns to the first mask layer;
forming a second mask layer filling spaces between portions of the spacer insulating layer;
forming first insulating patterns and a second insulating pattern using the first mask layer and the second mask layer as masks, the first insulating patterns having a line-and-space shape and the second insulating pattern horizontally surrounding the first insulating patterns;
forming a trench defined by the second insulating pattern by removing the first insulating patterns using a second photoresist pattern covering the second insulating pattern as a mask; and
forming a trench key in the scribe lane area by transferring a pattern of the trench to a lower region of the stacked structure using the second insulating pattern as a mask.

13. The method of claim 12, wherein
a width of the first photoresist patterns is equal to a width of a cell node of the chip area,
a distance between the first photoresist patterns is equal to a distance between cell nodes of the chip area, and
a pitch between the first photoresist patterns is equal to a pitch between the cell nodes of the chip area.

14. The method of claim 12, wherein
the second photoresist pattern is formed on the second insulating pattern and covers inner walls of the second insulating pattern, and
in the forming the trench, the removing the first insulating patterns is performed by a wet strip process.

15. The method of claim 12, wherein
the second photoresist pattern is formed on the second insulating pattern, and
inner walls of the second photoresist pattern are coplanar with inner walls of the second insulating pattern.

16. The method of claim 12, wherein
the scribe lane area comprises a key pattern including a plurality of trench key areas,
the trench key is formed in each of the plurality of trench key areas, and
the plurality of trench key areas are spaced apart from each other and arranged in a pinwheel shape.

17. The method of claim 12, wherein
the transferring the pattern of first photoresist patterns to the first mask layer includes removing portions of the first mask layer,
after the portions of the first mask layer are removed and the forming the second mask layer is performed, the portions of the first mask layer and the second mask layer together form a pattern in the line-and-space shape, wherein
a pitch of the pattern in the line-and-space shape formed by the portions of the first mask layer and the second mask layer is less than a pitch of the first photoresist patterns.

18. A method of manufacturing a semiconductor device, the method comprising:
forming a stacked structure including a first mask layer, a first insulating layer, and a second insulating layer on a substrate including a chip area and a scribe lane area;
forming a first photoresist pattern on the stacked structure, the first photoresist pattern including first portions having a line-and-space shape and a second portion horizontally surrounding the first portions;
transferring a pattern of the first photoresist pattern to the first mask layer by removing portions of the first mask layer using the first photoresist pattern as a mask to form remaining portions of the first mask layer;
forming a spacer insulating layer covering sidewalls of the remaining portions of the first mask layer;
forming a second mask layer filling spaces between portions of the spacer insulating layer;
forming first insulating patterns and a second insulating pattern, the first insulating patterns having a line and space shape, the second insulating pattern horizontally surrounding the first insulating patterns, the forming the first insulating patterns and the second insulating pattern including removing portions of the first insulating layer using the first mask layer and the second mask layer as masks;
forming a second photoresist pattern on the second insulating pattern, the second photoresist pattern exposing the first insulating patterns;
forming a trench defined by the second insulating pattern by removing the first insulating patterns using the second photoresist pattern as a mask;
removing the second photoresist pattern from surfaces of the second insulating pattern; and
forming a trench key by transferring a pattern of the trench to a lower region of the stacked structure using the second insulating pattern as a mask, the trench key passing through the second insulating layer and extending into the substrate.

19. The method of claim 18, wherein
a width of the first photoresist pattern is equal to a width of a cell node of the chip area,
the cell node of the chip area is among cell nodes of the chip area,
a distance between the first portions of the first photoresist patterns is equal to a distance between cell nodes of the chip area, and
a pitch between the first portions of the first photoresist patterns is equal to a pitch between the cell nodes of the chip area.

20. The method of claim 18, wherein
the second photoresist pattern is formed on the second insulating pattern and covers inner walls of the second insulating pattern, and
the removing the first insulating patterns is performed by a wet strip process.
